(19) United States
(12) Patent Application Publication
(10) Pub. No.: US 2023/0374663 A1
(43) Pub. Date: Nov. 23, 2023

(54) APPARATUS AND METHOD FOR PROCESSING SUBSTRATE

(71) Applicant: JUSUNG ENGINEERING CO., LTD., Gwangju-si (KR)

(72) Inventors: Jong Sik KIM, Gwangju-si (KR); Gu Hyun JUNG, Gwangju-si (KR); Won Woo Jung, Gwangju-si (KR)

(21) Appl. No.: 18/230,637

(22) Filed: Aug. 5, 2023

Related U.S. Application Data
(62) Division of application No. 17/256,647, filed on Dec. 28, 2020.

(30) Foreign Application Priority Data
Jun. 25, 2018 (KR) 10-2018-0072683

(51) Int. Cl. C23C 16/458; C23C 16/52; H01L 21/67; H01L 21/687; H01J 37/32; H01L 21/677

(52) U.S. Cl. CPC C23C 16/4584; C23C 16/52; H01L 21/67161; H01L 21/6875; H01L 21/67167; H01J 37/32743; H01L 21/67196; H01L 21/67796; H01L 21/67253; H01J 2237/20214

(57) ABSTRACT

A substrate processing apparatus includes a process chamber including a reaction space in which at least one substrate is mounted, a transfer chamber for transferring the at least one substrate to the process chamber, and a buffer chamber including a rotating device for rotating the at least one substrate by a predetermined angle, wherein the rotating device includes a rotating plate, a rotating shaft for rotating the rotating plate by the predetermined angle, a drive unit for driving the rotating shaft, a controller for controlling the drive unit, and a plurality of substrate support members, which are disposed on the rotating plate and on which the at least one substrate is mounted.

### TECHNICAL FIELD

Embodiments relate to a substrate processing apparatus and a substrate processing method using the same.

### BACKGROUND ART

Generally, semiconductor memory devices, liquid crystal display devices, organic light-emitting devices and the like are manufactured through a substrate processing process of performing a semiconductor process on a substrate many times so as to deposit and to layer a structure having a desired shape on the substrate.

The substrate processing process includes a process of depositing a predetermined thin film on a substrate, a photolithography process of exposing a selected region of the thin film, an etching process of removing the selected region of the thin film and the like. The substrate processing process is performed in a process chamber in which the optimal environment is provided.

Generally, an apparatus for processing substrates such as wafers is disposed in a process chamber and has a structure in which a plurality of susceptors are mounted on a disc, which is larger than each susceptor.

The substrate processing apparatus performs treatment of a substrate in such a way as to mount the substrate on the susceptor and to spray process gas containing a source material on the substrate so as to deposit and layer a structure having a desired shape on the substrate or to etch the substrate.

However, when a deposition process or an etching process is performed on the substrate, thickness of a film deposited on the substrate or etching degree of the substrate may locally become uneven. Hence, there is a need to provide a solution to this.

### INVENTIVE CONCEPT

### Technical Problem

The inventive concept is directed to apparatus and method for processing a substrate that substantially obviate one or more problems due to limitations and disadvantages of the related art.

### Technical Solution

An object of the inventive concept is to provide apparatus and method for processing a substrate, which are capable of improving uniformity in deposited thickness or etching degree throughout the substrate when a deposition process or an etching process is performed on the substrate.

The objects of the inventive concept are not limited to the above-mentioned objects. Other objects of the inventive concept, which have not been mentioned, will be apparent to those skilled in the art to which the inventive concept pertains, from the following detailed description.

To achieve these objects and other advantages and in accordance with the purpose of the inventive concept, as embodied and broadly described herein, a substrate processing apparatus includes a process chamber including a reaction space in which at least one substrate is mounted, a transfer chamber for transferring the at least one substrate to the process chamber, and a buffer chamber including a rotating device for rotating the at least one substrate by a predetermined angle, wherein the rotating device includes a rotating plate, a rotating shaft for rotating the rotating plate by the predetermined angle, a drive unit for driving the rotating shaft, a controller for controlling the drive unit, and a plurality of substrate support members disposed on the rotating plate and on which the at least one substrate is mounted.

The rotating device may rotate the substrate in a vacuum.

The transfer chamber may include a substrate transfer device for transferring the at least one substrate, and the plurality of substrate support members may be disposed so as not to interfere with the substrate transfer device within a rotational range of the predetermined angle.

Each of the plurality of substrate support members may include a plurality of slots, which are positioned at different levels so as to allow a plurality of substrates to be mounted thereon.

The plurality of substrate support members may be rotated by the predetermined angle in linkage with the rotating plate after the plurality of substrates are mounted on the plurality of slots.

The rotating device may include a plurality of rotating devices, which are provided in the buffer chamber.

The buffer chamber may include a first buffer chamber including a first rotating device, and a second buffer chamber including a second rotating device.

The controller may control the first rotating device and the second rotating device independently of each other.

In another aspect of the inventive concept, a substrate processing method includes firstly depositing a thin film on first and second substrates mounted in a process chamber, transferring the first and second substrates to a buffer chamber through a transfer chamber, rotating the first substrate by a first predetermined angle by driving a rotating device provided in the buffer chamber, rotating the second substrate by a second predetermined angle by driving a rotating device provided in the buffer chamber, transferring the first and second substrates to the process chamber through the transfer chamber, and secondly depositing thin film on the first and second substrates in the process chamber.

The first predetermined angle may be different from the second predetermined angle.

The first predetermined angle may be the same as the second predetermined angle.

The rotating the first substrate by a first predetermined angle may be performed in a vacuum, and the rotating the second substrate by a second predetermined angle may be performed in a vacuum.

It is to be understood that both the foregoing general description and the following detailed description of the inventive concept are exemplary and explanatory and are intended to provide further explanation of the inventive concept as claimed.

### Advantageous Effects

A substrate processing apparatus and a substrate processing method using the same in accordance with one embodiment may improve uniformity in deposited thickness or etching degree throughout the substrate when a deposition process or an etching process is performed on the substrate.

### DESCRIPTION OF DRAWINGS

FIG. 1 is a view schematically illustrating the construction of a substrate processing apparatus according to an embodiment of the inventive concept.

FIGS. 2(a) and 2(b) illustrate comparative examples of the substrate processing apparatus according to an embodiment of the inventive concept;

FIG. 3 is a plan view of a buffer chamber according to an embodiment of the inventive concept;

FIG. 4 is a plan view of a buffer chamber according to another embodiment of the inventive concept;

FIGS. 5(a) to 5(c) are plan views of a rotating plate shown in FIG. 4;

FIG. 6 is a cross-sectional view taken along line 1-1′ of FIG. 3 or line 2-2′ of FIG. 4;

FIG. 7 is a plan view of a buffer chamber according to a further embodiment, which is provided therein with a plurality of rotating devices;

FIG. 8 is a cross-sectional view taken along line 3-3′ in FIG. 7; and

FIGS. 9(a) and 9(b) are flowcharts explaining a substrate processing method according to an embodiment of the inventive concept.

### BEST MODE

Hereinafter, preferred embodiments of the inventive concept, which are capable of concretely realizing the above objects, will be described in detail with reference to the accompanying drawings. Although the embodiments may be subjected to various modifications and may have various different forms, specific embodiments will be illustrated in the drawings and will be described in detail in the detailed description.

It will be understood that, although the terms first, second, etc. may be used herein to describe various elements, these elements should not be limited by these terms. Relational terms, such as “on”/“upper”/“above”, “beneath”/“lower”/“below” and the like, used herein do not require specific physical or logical relationships or sequences among the elements, and are only used to distinguish one element from another.

The terminology used in the present inventive concept is for the purpose of describing particular embodiments only, and is not intended to limit the inventive concept. As used in the inventive concept and the appended claims, the singular forms are intended to include the plural forms as well, unless context clearly indicates otherwise.

Hereinafter, a substrate processing apparatus according to an embodiment will be described with reference to the accompanying drawings.

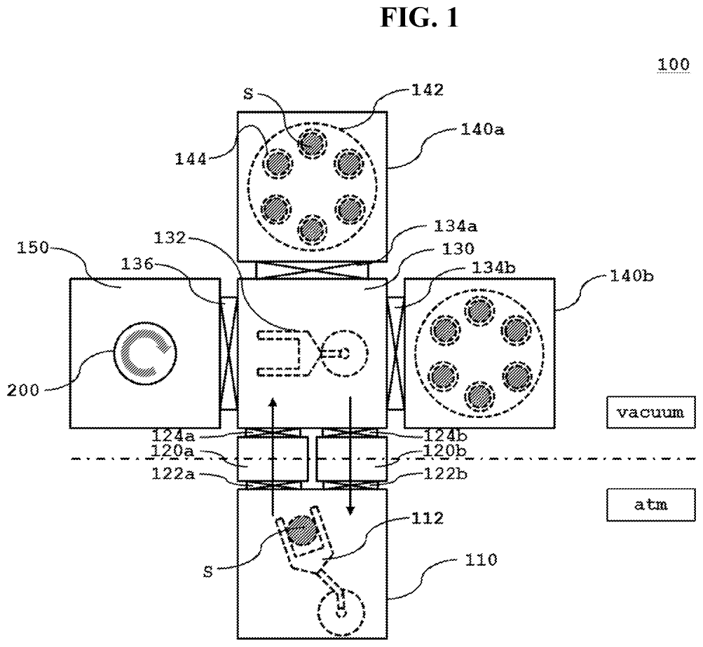

FIG. 1 is a view schematically illustrating the construction of the substrate processing apparatus according to an embodiment of the inventive concept.

As illustrated in FIG. 1, the substrate processing apparatus 100 may include an equipment front end module (EFEM) 110, a load lock chamber 120, a transfer chamber 130, a process chamber 140 and a buffer chamber 150, a gate being provided between adjacent chambers (or modules). Here, each of the gates may have a size sufficient to allow a substrate S to be transferred into/out of the associated chamber.

The EFEM 110 may be maintained at the atmospheric state, and may be provided therein a robot arm 112 so as to transfer the substrate S to the load lock chamber 120.

The load lock chamber 120 may include an introduction load lock chamber 120a connected to one side of the transfer chamber 130, and a discharge load lock chamber 120b connected to the other side of the transfer chamber 130, and may serve as an interface between an atmospheric process and a vacuum process.

The introduction load lock chamber 120a may be connected to EFEM 110 via a first-first gate 122a.

The discharge load lock chamber 120b may be connected to EFEM 110 via a first-second gate 122b.

The transfer chamber 130 may be provided therein with a substrate transfer device 132, which is constructed so as to transfer the substrate S that is introduced thereinto from the introduction load lock chamber 120a to at least one process chamber 140 and/or the buffer chamber 150 or so as to discharge the substrate S that is transferred thereto from the at least one process chamber 140 and/or the buffer chamber 150 to the discharge load lock chamber 120b.

Here, a robot arm may be used as an example of the substrate transfer device 132. The robot arm may be configured to grip the substrate S in the transfer stage. Furthermore, the robot arm may serve to perform transfer of the substrate S among the load lock chamber 120, the process chamber 140 and the buffer chamber 150 by virtue of linear movement, vertical movement and rotation movement thereof.

The one or more process chamber 140a and 140b may be connected to the transfer chamber 130 via a third gate 134a, 134b, and may be provided therein with a reaction space for deposition or etching of the substrate S that is transferred thereto from the transfer chamber 130.

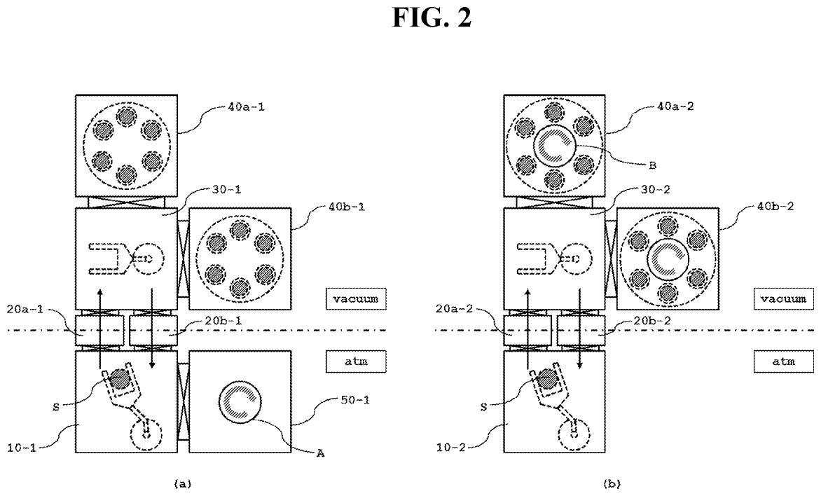

The buffer chamber 150 may be connected to the transfer chamber 130 via a fourth gate 136, and may be provided therein with a rotating device 200, which is constructed to rotate the substrate S, which is partially deposited, by a predetermined angle so as to improve uniformity in thickness of a film deposited on the substrate S or in etching degree of the substrate S. Here, the internal pressure in the buffer chamber 150 may be maintained at a process pressure, that is, in a vacuum or in a pressure between vacuum and atmospheric pressure. Prior to inventive concept of construction of the rotating device 200, the buffer chamber 150 according to an embodiment will now be described in comparison with FIGS. 2(a) and 2(b).

FIGS. 2(a) and 2(b) illustrate comparative examples of the substrate processing apparatus according to an embodiment of the inventive concept.

Since an EFEM 10-1 or 10-2, an introduction load lock chamber 20a-1 or 20a-2, a discharge load lock chamber 20b-1 or 20b-2 and a transfer chamber 30-1 or 30-2, which are shown in FIG. 2(a) and FIG. 2(b), carry out the same functions as those of the EFEM 110, the introduction load lock chamber 120a, the discharge load lock chamber 120b and the transfer chamber 130, description thereof will be omitted. Furthermore, in the following inventive concept, description that overlaps the description of the above-described embodiment will not be given again, and only the difference therebetween will be described.

According to the comparative example illustrated in FIG. 2(a), a buffer chamber 50-1, which is provided therein with a rotating device A, is connected to the EFEM 10-1 via a gate, and the internal pressure in the buffer chamber 50-1 is maintained at atmospheric pressure.

For example, a venting time from the process pressure (or vacuum) to atmospheric pressure is assumed to be T, and a pumping time from atmospheric pressure to the process pressure (or vacuum) is assumed to be T.

As illustrated in FIG. 2(a), when the internal pressure in the buffer chamber 50-1 is maintained at atmospheric pressure, the substrate S that has been at least partially deposited is transferred to the EFEM 10-1 by venting the interior of the discharge load lock chamber 20b-1, and the substrate S that has been at least partially deposited in the buffer chamber 50-1 is rotated by a predetermined angle. Subsequently, the substrate that has been rotated by the predetermined angle is transferred to the process chambers 40a-1 and 40b-1 by pumping the interior of the introduction load lock chamber 20a-1, whereby the substrate S is subjected to the remaining deposition process therein. In this case, a time of a total of 2 T is further taken to vent the interior of the discharge load lock chamber 20b-1 and then to pump the interior of the introduction load lock chamber 20a-1.

In contrast, according to an embodiment of the inventive concept shown in FIG. 1, since the internal pressure in the buffer chamber 150 is maintained at the process pressure, it is possible to omit the process of venting the interior of the discharge load lock chamber 120b and the process of pumping the interior of the introduction load lock chamber 120a, thereby saving a time of about 2 T. Accordingly, since the total process time in a thin-film deposition apparatus is reduced, it is possible to improve the operation rates of the semiconductor equipment and to ensure high mass-productivity.

According to another comparative example shown in FIG. 2(b), a rotating device B is provided in each of process chambers 40a-2 and 40b-2.

As illustrated in FIG. 2(b), when the process chambers 40a-2 and 40b-2 are respectively provided therein with the rotating devices B, the components, which constitute the rotating device B, thermally expand under high process temperature, that is, under about 400° C., or the components, which has low heat resistance, are deformed, thereby increasing the possibility that the rotating device B malfunctions or breaks. Furthermore, there is a difficulty in rotating the substrate S by the predetermined angle while a deposition or etching process is performed, thereby deteriorating the quality of the deposited film.

In contrast, according to an embodiment of the inventive concept shown in FIG. 1, the rotating device 200 is provided in the buffer chamber 150, which is connected to the transfer chamber 130 via the fourth gate 136, rather than in the process chambers 140a and 140b, and the buffer chamber 150 does not include an additional heater, thereby creating a low-temperature atmosphere compared to the interiors of the process chambers 140a and 140b. Consequently, it is possible to reduce breakage or defect ratio of the rotating device 200. In addition, since the substrate S is rotated in an additional space other than the space in which the deposition or etching process is performed, it is easy to rotate the substrate to a specific angle, and it is possible to improve uniformity in thickness of the deposited film or etching degree of the substrate S.

Although not illustrated in the drawings, according to another embodiment of the inventive concept, the buffer chamber 150 may be the load lock chamber 120. Alternatively, the rotating device 200 may be provided in the load lock chamber 120. When an additional space, which is required to accommodate the rotating device 200, that is, the buffer chamber 150 is omitted, it is possible to improve space availability.

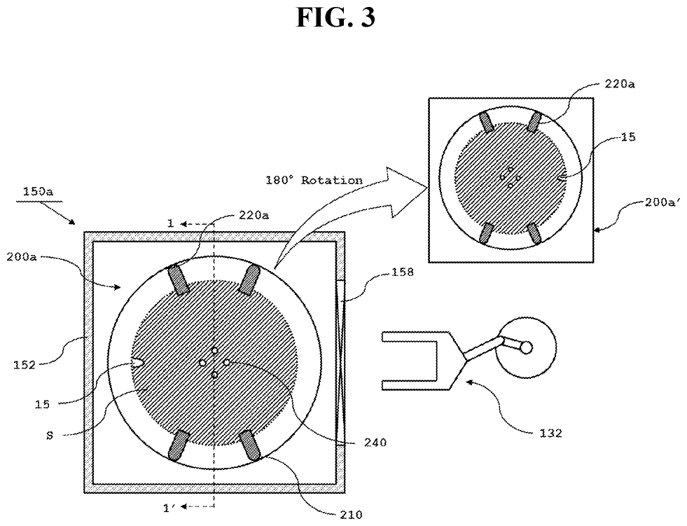

Hereinafter, the buffer chamber according to embodiments of the inventive concept will be described in more detail with reference to FIGS. 3 to 6.

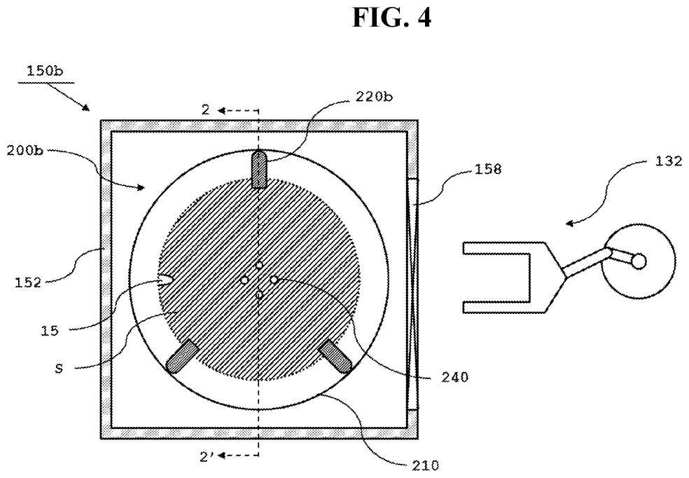

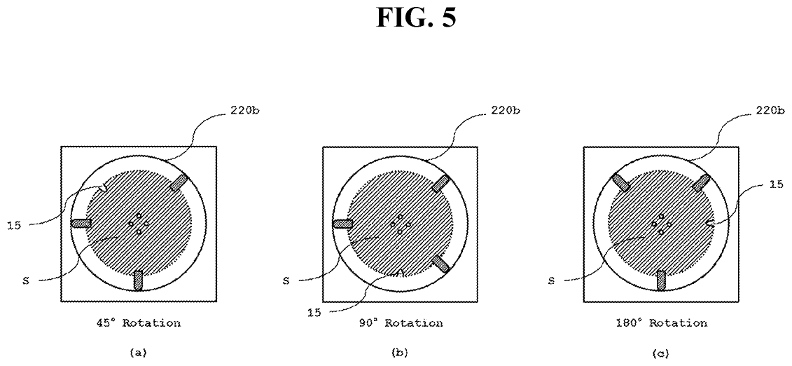

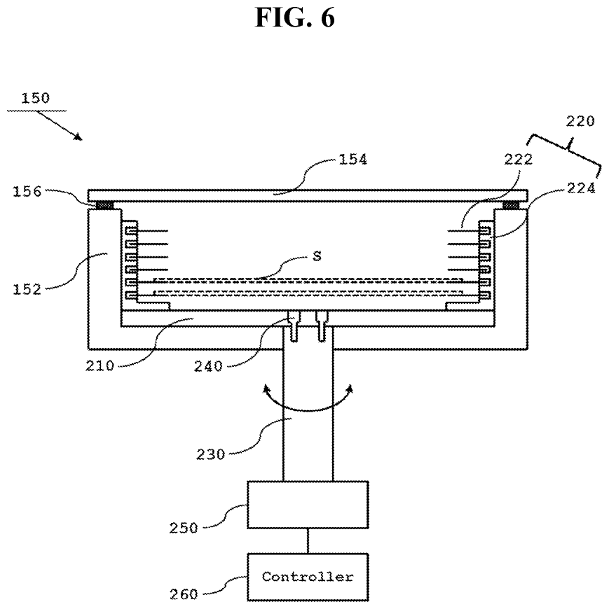

FIG. 3 is a plan view of the buffer chamber according to an embodiment of the inventive concept. FIG. 4 is a plan view of the buffer chamber according to another embodiment of the inventive concept. FIG. 5 is a plan view of the rotating plate shown in FIG. 4. FIG. 6 is a cross-sectional view taken along line 1-1′ of FIG. 3 or line 2-2′ of FIG. 4.

Hereinafter, the construction of the rotating device will be described first with reference to FIG. 6 for convenience of description.

Referring to all of FIGS. 3, 4 and 6, the buffer chamber 150 may include a chamber body 152, an upper plate provided on the chamber body 152, the rotating device 200 disposed in the interior space defined between the chamber body 152 and the upper plate 154, a sealing ring 156 for maintaining the air seal between the chamber body 152 and the upper plate 154, and a gate 158, which is formed through at least a portion of a lateral side wall of the chamber body 152 so as to allow the substrate S to be introduced and discharged therethrough.

The rotating device shown in FIG. 6 may include a rotating plate 210, a plurality of substrate support members 220, which are disposed on the rotating plate 210 and on which at least one substrate S is mounted, a rotating shaft 230 for rotating the rotating plate 210 by a predetermined angle, at least one fixing pin 240 for closely fixing the rotating plate 210 to the rotating shaft 230 such that the rotating plate 210 is rotated together with the rotating shaft 230, a drive unit 250 for transmitting power to the rotating shaft 230, and a controller 260 for controlling the drive unit 250.

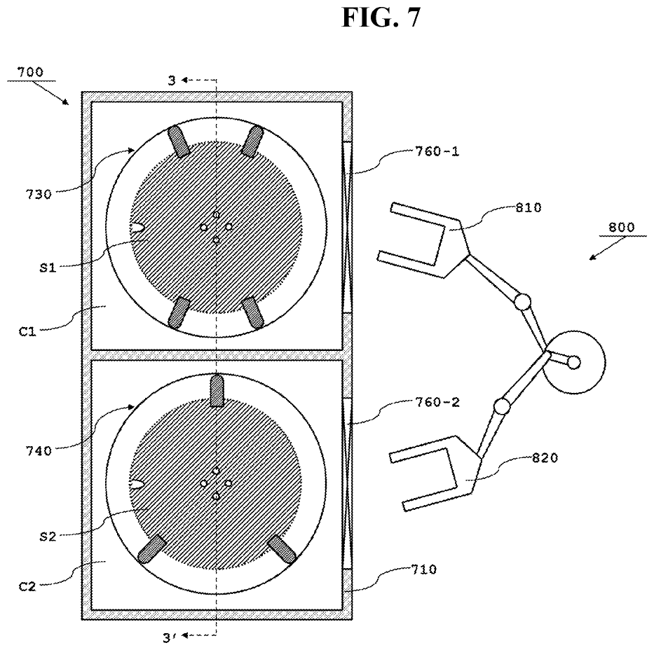

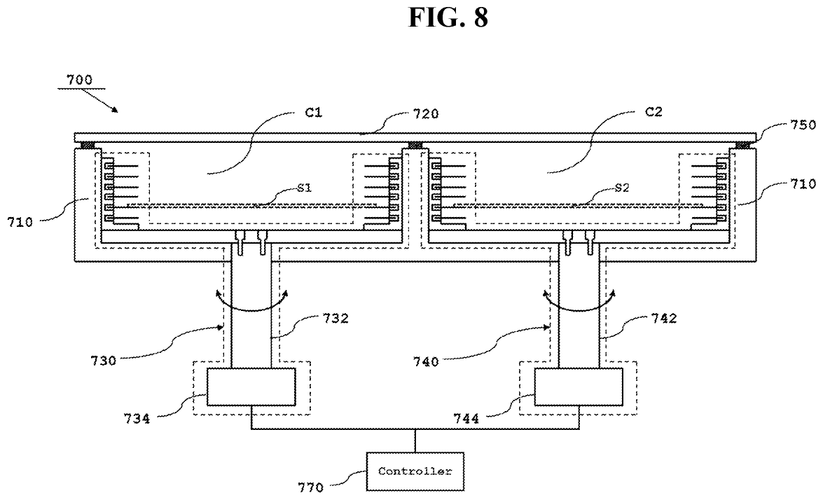

Although only one rotating device 200 is illustrated in FIGS. 3 to 6 as being provided in the buffer chamber 150, a plurality of rotating devices may be provided in order to improve process efficiency. A description thereof will be given with reference to FIGS. 7 and 8 later.

The rotating plate 210 may be coupled to the bottom of the chamber body 152, and may be rotated together with the rotating shaft 230 upon rotation of the rotating shaft 230. Although a disc-shaped rotating plate 210 is provided in the embodiment, the rotating plate is not limited thereto, and the size and shape of the rotating plate 210 may be variously changed depending on the size and shape of the substrate S.

Each of the plurality of substrate support members 220 may include a plurality of slots 222, which are positioned at different levels so as to allow at least one substrate S to be horizontally mounted thereon, and a side support 224 for supporting the plurality of slots 222 at the side surface thereof. When at least one substrate S is mounted on the plurality of slots 222, the at least one substrate S may be rotated together with the plurality of slots 222 and the rotating plate 210 by a predetermined angle. Here, the number of the plurality of slots 222 may be set so as to correspond to the number of process chambers 140 connected to the transfer chamber 130 and the number of substrates S, which can be mounted in each of the process chambers 140. Accordingly, since it is possible to load substrates S into the buffer chamber 150 and to collectively rotate the substrates S after a partial deposition process in each of the process chambers 140 is performed, it is possible to reduce the total process time.

The rotating shaft 230 may be coupled to the lower portion of the rotating plate 210 by means of at least one fixing pin 240 so as to rotate the rotating plate 210 by a predetermined angle.

The drive unit 250 is provided under the rotating shaft 230 so as to transmit power required to rotate the rotating shaft 230. The drive unit 250 may be embodied in any manner as long as the drive unit 250 is able to rotate the rotating shaft 230. For example, the drive unit 250 may be embodied by a pneumatic driving machine, a mechanical driving machine or the like. The drive unit 250 may also be provided outside the process chamber 100.

The controller 260 may control the drive unit 250 such that the rotating shaft 230 is rotated by a predetermined angle or in a predetermined direction.

Although not illustrated in the drawings, the rotating device 200 according to an embodiment may further include at least one sensor (not shown) for detecting whether or not at least one substrate S is accurately mounted at a predetermined position on the plurality of substrate support members 220.

Referring again to FIGS. 3 and 4, a structure in which the plurality of substrate support members 220 are disposed on a flat surface will be described.

As illustrated in FIGS. 3 and 4, a notch 15 may be formed in the substrate S, which is mounted on the plurality of substrate support members 220a or 220b. The notch 15 may be used so as to distinguish the upper surface and the lower surface of the substrate S, to determine whether the notch 15 is rotated with respect to the rotating plate 210 and to detect the rotational angle, the rotational direction and the like. In the embodiment shown in FIGS. 3 and 4, for example, the surface of the substrate S in which the notch 15 is formed becomes the upper surface of the substrate S, and process gas is sprayed onto the upper surface of the substrate S in which the notch 15 is formed so as to perform a process such as deposition, etching or the like on the upper surface of the substrate S.

The plurality of substrate support members 220a or 220b may be disposed so as not to interfere with the substrate transfer device 132 disposed in the transfer chamber 130 within a predetermined range of rotational angle.

The rotating device 200a according to an embodiment shown in FIG. 3 may include four substrate support members 220a, which are disposed on the same face so as to face each other and which are capable of being rotated together with the rotating plate 210 by about 180° in clockwise or counterclockwise direction by driving the rotating shaft 230. However, it will be apparent to those skilled in the art that the predetermined rotational angle of the rotating plate 210 is not limited 180° and is set to be any rotational angle as desired by a user using the rotating device 200a.

Reference numeral “200a′” in FIG. 3 is a plan view illustrating the state in which at least one substrate S, which is mounted on four substrate support members 220a, is rotated by about 180°. Here, the rotational angle, the rotational direction or the like of the substrate S may be perceived by means of the notch 15 formed in the substrate S.

As described in detail in FIG. 1, when a deposition process is performed in the state in which the substrate S is not rotated, the thickness of the deposited film may become uneven, for example, because process gas is not sprayed uniformly throughout the substrate S. For example, the deposition may be locally concentrated only on one surface of the substrate S. Here, the substrate processing apparatus according to an embodiment of the inventive concept may perform a deposition process in such a way as to transfer the substrate S to the buffer chamber 150a, which is provided with the rotating device 200a, through the transfer chamber 130, to rotate the substrate S by about 180° in a clockwise or counterclockwise direction in the buffer chamber 150a, and to transfer the substrate S that has been rotated by about 180° to the process chamber 140 again where the other surface of the substrate S is deposited, thereby completing the deposition process.

As described above, when the substrate S is rotated by a predetermined angle using the rotating device 200a, which is provided in the buffer chamber 150a, a deposited film having a uniform thickness may be obtained throughout the upper surface of the substrate S.

As illustrated in FIG. 4, a rotating device 200b according to another embodiment may include three substrate support members 220b, which are disposed on the same face so as not to interfere with the substrate transfer device 132 provided in the transfer chamber 130. Here, the phrase that the substrate support members 220b are disposed so as not to interfere with the substrate transfer device 132 may be defined as the substrate support members 220b being disposed within a range within which linear movement, vertical movement and rotation of the substrate transfer device 132 for mounting (or loading) the substrate S on the rotating device 200b in the buffer chamber 150b is not obstructed.

FIGS. 5(a) to 5(c) are plan views illustrating states in which the substrate S is rotated by predetermined angles by means of the rotating device 200b according to another embodiment shown in FIG. 4. Here, the rotational angle, the rotational direction and the like of the substrate S may be perceived through the notch 15 formed in the substrate S.

FIG. 5(a) illustrates a state in which the substrate S is rotated by about 45° in a clockwise direction from the initial position thereof. FIG. 5(b) illustrates a state in which the substrate S is rotated by about 90° in a counterclockwise direction from the initial position thereof. FIG. 5(c) illustrates a state in which the substrate S is rotated by about 180° in a clockwise or counterclockwise direction from the initial position thereof.

The rotational angle of the substrate S is not limited to the angles of 45? 90° and 180°, and the substrate S may be rotated by any angle as desired by a user. In the rotational direction, the substrate S may also be rotated in any direction, for example, in any direction of clockwise and counterclockwise.

Accordingly, it is possible for a user to control the shape or thickness of a deposited film in various manners by rotating the substrate S by a specific angle using the rotating device 200b provided in the buffer chamber 150b.

Hereinafter, a buffer chamber according to a further embodiment, which is provided therein with a plurality of rotating devices, will be described with reference to FIGS. 7 and 8.

FIG. 7 is a plan view of the buffer chamber according to the further embodiment, which is provided therein with the plurality of rotating devices. FIG. 8 is a cross-sectional view taken along line 3-3′ in FIG. 7.

The buffer chamber shown in FIGS. 7 and 8 is different from the buffer chamber shown in FIGS. 3 to 6 in that the former includes the plurality of rotating devices.

Referring to FIGS. 7 and 8, the buffer chamber 700 according to the further embodiment may include a chamber body 710, an upper plate 720 disposed on the top of the chamber body 710, a first rotating device 730 and a second rotating device 740, which are respectively provided in a plurality of internal spaces C1 and C2 defined between the chamber body 710 and the upper plate 720, a sealing ring 750 for maintaining the air seal between the chamber body 710 and the upper plate 720, a plurality of gates 760-1 and 760-2, which are formed through at least a portion of a lateral side wall of the chamber body 710 so as to allow the substrate S to be introduced and discharged therethrough, and a controller 770 for controlling operation of the first and second rotating devices 730 and 740.

Here, since the components of the first rotating device 730 and the second rotating device 740 are substantially the same as the components of the rotating device shown in FIGS. 3 to 6 in structures and functions, reference numerals and redundant description thereof are omitted, and only the difference therebetween will be mainly described hereinafter.

The chamber body 710 may be configured to have an “E” shape so as to accommodate therein the first rotating device 730 and the second rotating device 740, and may define therein a plurality of internal spaces C1 and C2. Here, each of the internal pressures in the plurality of internal spaces C1 and C2 may be maintained at a process pressure, that is, in a vacuum or in a pressure between vacuum and atmospheric pressure. When the interior of the buffer chamber 700 is divided into a plurality of spaces rather than into a single space, the volume, which has to be maintained at a vacuum, is reduced, thereby making it easy to maintain or control the process pressure of the interior of the buffer chamber.

The controller 770 may independently control a first drive unit 734 and a second drive unit 744 so as to rotate at least one first substrate S1 mounted on the first rotating device 730 and a second substrate S2 mounted on the second rotating device 740 by different rotational angles and/or in different rotational directions.

Alternatively, the controller 770 may control the first and second drive units 734 and 744 so as to rotate the substrates S1 and S2 mounted on the first and second rotating devices 730 and 740 by the same rotational angle and/or in the same rotational direction while driving the first rotating device 730 and the second rotating device 740 independently of each other.

Although not illustrated in the drawings, alternatively, a first rotating shaft 732 and a second rotating shaft 734, which are respectively included in the first rotating device 730 and the second rotating device 740, may be connected to a single drive unit (not shown) and may be driven simultaneously, and the controller 770 may set or control the rotational angle and/or the rotational direction of the substrates S1 and S2 mounted on the first and second rotating devices 730 and 740 to be the same as each other.

Although two rotating devices 730 and 740 are illustrated in the embodiment, it will be apparent to those skilled in the art that the inventive concept is not limited thereto and that various numbers of rotating devices may be provided in the buffer chamber 700.

Furthermore, although the plurality of rotating devices 730 and 740, which are provided in a single buffer chamber 700, are illustrated in FIGS. 7 and 8, it will be apparent to those skilled in the art that the inventive concept is not limited thereto and that a plurality of rotating devices, which are respectively provided in a plurality of buffer chambers, fall within the scope of the inventive concept.

A substrate transfer device 800, which is provided in a transfer chamber (not shown), may be a dual robot arm, which includes a plurality of arms 810 and 820. Here, the first arm 810 and the second arm 820 may respectively mount (or load) the substrates S1 and S2 on the first rotating device 730 and the second rotating device 740.

As described previously, when N rotating devices (N being an integer) are provided in the buffer chamber 700, it is possible to reduce the time required to rotate the substrates S1 and S2 to 1/N, thereby ensuring high mass-productivity.

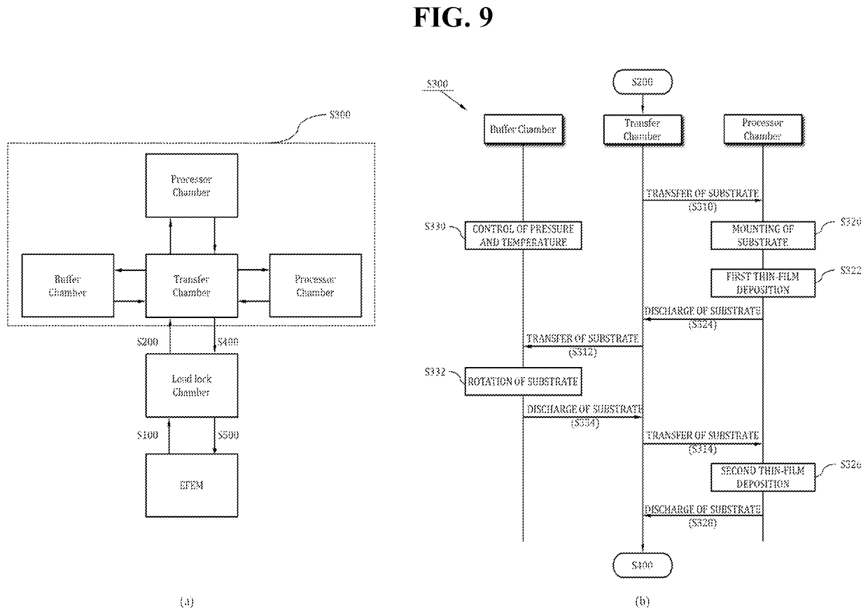

Hereinafter, a substrate processing method will be described with reference to FIGS. 9(a) and 9(b).

FIGS. 9(a) and 9(b) are flowcharts explaining the substrate processing method according to an embodiment of the inventive concept.

As illustrated in FIG. 9(a), the substrate processing method according to an embodiment of the inventive concept may include an operation (S100) of transferring a substrate S to the load lock chamber 120 from the EFEM 110 in an atmospheric pressure, an operation (S200) of introducing the substrate S into the transfer chamber 130 from the load lock chamber 120 in a vacuum, an operation (S300) of depositing a thin film on the substrate S, which has been introduced into the transfer chamber 130, an operation (S400) of discharging the deposited substrate S to the load lock chamber 120 from the transfer chamber 130, and an operation (S500) of transferring the deposited substrate S to the EFEM 110 from the load lock chamber 120 in atmospheric pressure.

Hereinafter, the operation (S300) of depositing a thin film on the substrate S, which has been introduced into the transfer chamber 130, will be described in detail with reference to FIG. 9(b).

When the transfer chamber 130 transfers the substrate S into the process chamber 140 (S310) after the operation (S200), the process chamber 140 may perform an operation (S320) of mounting the substrate S, an operation (S322) of firstly depositing a thin film on the substrate S and an operation (S324) of discharging the substrate S, in sequence.

In the operation (S320) of mounting the substrate S, the at least one substrate S that has been introduced from the transfer chamber 130 may be mounted on a plurality of susceptors.

In the operation (S320) of firstly depositing a thin film on the substrate, the deposition process may be performed by spraying process gas onto the upper surface of the substrate S mounted in the process chamber 140. During the deposition process, the interior of the process chamber 140 may be maintained at a process pressure (in a vacuum or in a pressure between vacuum and atmospheric pressure, the same shall apply hereafter) but may be maintained at atmospheric pressure during maintenance.

In the first thin-film deposition operation (S322), the thickness of the deposited film may become uneven, for example, because the process gas is not sprayed uniformly throughout the substrate S. For example, the deposition may be locally concentrated only on one surface of the substrate S.

In the operation (S324) of discharging the substrate S, the substrate S that has been deposited in the operation (S322) may be discharged to the transfer chamber 130. Subsequently, the transfer chamber 130 may transfer the substrate S into the buffer chamber 150 (S312).

Prior to the operation (S312), an operation (S330) of controlling the pressure and temperature in the buffer chamber 150 such that the internal pressure in the buffer chamber 150 is maintained at a process pressure, that is, in a vacuum or in a pressure between vacuum and atmospheric pressure and such that the temperature in the buffer chamber 150 becomes lower than the temperature in the process chamber 140a or 140b may be previously performed.

When the internal pressure in the buffer chamber 150 is controlled to be the process pressure, venting and pumping operations in the load lock chamber 120 may be omitted. Consequently, since the total process time in the thin-film deposition apparatus is reduced, it is possible to improve an operation rate of the semiconductor equipment and to ensure high mass-productivity. In addition, when the internal temperature in the buffer chamber 150 is controlled to be lower than the internal temperature in the process chamber 140, it is possible to reduce breakage or defect rate of the rotating device 200.

After the operation (S12), the buffer chamber 150 may perform an operation (S332) of rotating the substrate S and an operation (S334) of discharging the substrate S, in sequence.

In the operation (S332) of rotating the substrate S, the deposited substrate S may be rotated by a predetermined angle by means of the rotating device 200 provided in the buffer chamber 150. In the operation (S332), when the buffer chamber 150 is provided therein with a plurality of rotating devices 200, a plurality of substrates, which are mounted on the plurality of rotating devices 200, may be rotated by different rotational angles and/or in different rotational directions.

For example, the operation (S332) of rotating the substrate S may include an operation of rotating a first substrate mounted on a first rotating device by a first predetermined angle and an operation of rotating a second substrate mounted on a second rotating device by a second predetermined angle. Here, the first predetermined angle and the second predetermined angle may be different from each other. However, the inventive concept is not limited thereto. Alternatively, the first predetermined angle and the second predetermined angle may be set to be the same.

In the operation (S334) of discharging the substrate S, the substrate S that has been rotated by the predetermined angle in the operation (S332) may be discharged to the transfer chamber 130. Subsequently, the transfer chamber 130 may transfer the substrate S into the process chamber 140 (S314).

After the operation (S314), the process chamber 140 may perform an operation (S326) of secondly depositing thin film on the substrate and an operation (S328) of discharging the substrate, in sequence.

In the operation (S326) of secondly depositing a thin film on the substrate S, the deposition operation may be performed by spraying process gas onto the upper surface of the substrate S that has been rotated by the predetermined angle in the operation (S322), and the remaining thin film may be deposited on the other surface of the substrate S.

As described previously, since the operation (S312) of rotating the substrate S by the predetermined angle is performed between the first thin-film deposition operation (S322) and the second thin-film deposition operation (S326), it is possible to obtain deposited film having a uniform thickness throughout the entire upper surface of the substrate S. In addition, it is possible to form thin films having various shapes by controlling the rotational angle of the substrate S to a specific angle as desired by a user.

Subsequently, in the operation (S328) of discharging the substrate S, the substrate S including the deposited film having the uniform thickness may be discharged to the transfer chamber 130, thereby completing the operation (S300) of depositing thin film on the substrate S.

Although only some embodiments have been described, various embodiments may be realized other than the above-described embodiments. The technical features of the above-described embodiments may be combined with each other in various manners and may thus be realized as a new embodiment as long as the features are compatible with each other.

The substrate processing apparatus and the substrate processing method using the apparatus may be applied to processes of manufacturing a flat display device, a solar cell and the like, in addition to the process of depositing a thin film on a substrate of a semiconductor device.

According to at least one embodiment of the inventive concept, the following effects are obtained.

According to an embodiment, since a rotating device having a simple and robust structure is used to rotate a substrate by a predetermined angle, it is possible to improve uniformity both in thickness of a deposited film and in etching degree of the substrate.

In addition, there is an effect of being capable of manufacturing a substrate by rotating the substrate by a predetermined angle even in a high-temperature atmosphere.

The effects of the inventive concept are not limited to those mentioned above. It should be understood that the effects of the inventive concept include all effects that can be inferred from the foregoing description of the inventive concept.

It will be apparent to those skilled in the art that various modifications and variations can be made in the inventive concept without departing from the spirit or scope of the inventive concept. Thus, it is intended that the inventive concept cover the modifications and variations of this inventive concept provided they come within the scope of the appended claims and their equivalents.

### INDUSTRIAL APPLICABILITY

Embodiments are usable in an apparatus and method for a substrate which may improve uniformity in deposited thickness or etching degree throughout the substrate when a deposition process or an etching process is performed on the substrate.

1. A substrate processing method, comprising:
firstly depositing a thin film on first and second substrates mounted in a process chamber;
transferring the first and second substrates to a buffer chamber through a transfer chamber;
rotating the first substrate by a first predetermined angle by driving a first rotator provided in a first space of a plurality of internal spaces defined between the buffer chamber;
rotating the second substrate by a second predetermined angle by driving a second rotator provided in a second space of the plurality of internal spaces of the buffer chamber;
retransferring the first and second substrates to the process chamber through the transfer chamber; and
secondly depositing thin film on the first and second substrates in the process chamber.

2. The substrate processing method according to claim 1, wherein the first predetermined angle is different from the second predetermined angle.

3. The substrate processing method according to claim 1, wherein the first predetermined angle is the same as the second predetermined angle.

4. The substrate processing method according to claim 1, wherein the rotating the first substrate by a first predetermined angle is performed in a vacuum, and
wherein the rotating the second substrate by a second predetermined angle is performed in a vacuum.

5. The substrate processing method according to claim 1, wherein the rotating the first substrate by a first predetermined angle is performed in a clockwise direction from the initial position thereof, and wherein the rotating the second substrate by a second predetermined angle is performed in a clockwise direction from the initial position thereof.

6. The substrate processing method according to claim 1, wherein the rotating the first substrate by a first predetermined angle is performed in a counterclockwise direction from the initial position thereof, and wherein the rotating the second substrate by a second predetermined angle is performed in a counterclockwise direction from the initial position thereof.

7. The substrate processing method according to claim 1, wherein the rotating the first substrate by a first predetermined angle is performed in a clockwise direction from the initial position thereof, and wherein the rotating the second substrate by a second predetermined angle is performed in a counterclockwise direction from the initial position thereof.

8. The substrate processing method according to claim 1, wherein transferring the first and second substrates to a buffer chamber is performed by a dual robot arm, which includes a plurality of arms in the transfer chamber.

9. The substrate processing method according to claim 8, wherein retransferring the first and second substrates to a buffer chamber is performed by the dual robot arm.
